(19) United States
(12) Patent Application Publication
(10) Pub. No.: US 2023/0301101 A1
(43) Pub. Date: Sep. 21, 2023

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Junghwan Lee, Seoul (KR); Yujin Kwon, Suwon-si (KR); Jaehong Yoo, Suwon-si (KR); Hyunmin Cho, Yongin-si (KR)

(21) Appl. No.: 18/046,139

(22) Filed: Oct. 12, 2022

(30) Foreign Application Priority Data
Mar. 16, 2022 (KR) 10-2022-0032487

(51) Int. Cl. H01L 27/11582; H01L 27/11556

(52) U.S. Cl. CPC H01L 27/11582; H01L 27/11556

(57) ABSTRACT

An integrated circuit memory device includes a stack structure on a semiconductor substrate. The stack structure includes a first gate stack group, which includes a plurality of spaced-apart first gate electrodes, and a second gate stack group, which includes a plurality of spaced-apart second gate electrodes. The second gate stack group extends on the first gate stack group so that the first gate stack group extends between the second gate stack group and the substrate. A plurality of active channel structures are provided, which penetrate vertically through the second gate stack group as upper channel structures and through the first gate stack group as lower channel structures. A plurality of dummy channel structures are provided, which penetrate vertically through the second gate stack group but not through the first gate stack group.

### REFERENCE TO PRIORITY APPLICATION

This application claims the benefit under 35 USC 119(a) of Korean Patent Application No. 10-2022-0032487, filed Mar. 16, 2022, the disclosure of which is hereby incorporated herein by reference.

### BACKGROUND

The present inventive concept relates to integrated circuit devices and, more particularly, to highly integrated data storage systems containing three-dimensional (3D) memory devices therein.

In data storage systems requiring data storage, an integrated circuit device capable of storing high-capacity data is required. Accordingly, methods for increasing the data storage capacity of an integrated circuit device are being researched. As an example, a method for increasing the data storage capacity of an integrated circuit device includes forming memory cells that are arranged three-dimensionally instead of two-dimensionally.

### SUMMARY

Example embodiments provide an integrated circuit device having higher integration and improved reliability.

Example embodiments provide a data storage system including an integrated circuit device having higher integration and improved reliability.

According to example embodiments, an integrated circuit device includes a source structure having a memory cell region and a first connection region therein. A stack structure is provided, which is disposed on the source structure, and includes a first gate stack group and a second gate stack group on the first gate stack group. The first gate stack group includes a plurality of first gate electrodes, and the second gate stack group includes a plurality of second gate electrodes. A plurality of channel structures are provided on the memory cell region, which penetrate through the stack structure and are connected to the source structure. In addition, a plurality of first dummy vertical structures are provided on the first connection region, which pass through at least a portion of the stack structure. A plurality of second dummy vertical structures are provided on the memory cell region, which pass through the second gate stack group, and are disposed between the plurality of channel structures and the plurality of first dummy vertical structures. Each of the plurality of channel structures includes a lower channel structure passing through the first gate stack group and an upper channel structure passing through the second gate stack group. The plurality of second dummy vertical structures penetrate through an uppermost one of the second gate electrode among the plurality of second gate electrodes. And, lower ends of the plurality of second dummy vertical structures are disposed on a level higher than a level of at least one of the plurality of first gate electrodes.

According to further embodiments, an integrated circuit device includes a source structure having a memory cell region, a first connection region, and a second connection region therein. A plurality of gate electrodes are provided, which are stacked on the memory cell region of the source structure and include pad regions extending in a first direction and forming a step structure on the first connection region. The plurality of gate electrodes include a first gate stack group and a second gate stack group on the first gate stack group. A plurality of sacrificial layers are provided, which are stacked on the second connection region of the source structure and are disposed on the same level as the gate electrodes. The plurality of sacrificial layers include a first sacrificial stack group and a second sacrificial stack group on the first sacrificial stack group. A plurality of channel structures are provided, which are connected to the source structure by penetrating through the plurality of gate electrodes, on the memory cell region. A plurality of first dummy vertical structures pass through the pad regions of the plurality of gate electrodes, on the first connection region. And, a plurality of second dummy vertical structures pass through the second sacrificial stack group, on the second connection region.

According to additional embodiments, a data storage system includes an integrated circuit storage device having a lower structure therein that includes a substrate (and circuit elements on the substrate), and an upper structure on the lower structure. In addition, an input/output pad is provided, which is electrically connected to the circuit elements. A controller is provided, which is electrically connected to the integrated circuit storage device through the input/output pad, and controls the storage device. The upper structure includes a source structure (including a memory cell region) and a first connection region, and a stack structure disposed on the source structure. The stack structure includes a first gate stack group and a second gate stack group on the first gate stack group. The first gate stack group includes a plurality of first gate electrodes, and the second gate stack group includes a plurality of second gate electrodes. A plurality of channel structures are provided, which are connected to the source structure by penetrating through the stack structure, on the memory cell region. A plurality of first dummy vertical structures are provided that pass through at least a portion of the stack structure, on the first connection region. A plurality of second dummy vertical structures are provided that pass through the second gate stack group (on the memory cell region), and are disposed between the plurality of channel structures and the plurality of first dummy vertical structures. Lower ends of the plurality of second dummy vertical structures are disposed on a level higher than a level of the plurality of first gate electrodes. The plurality of first and second gate electrodes provide first and second pad regions, respectively. These first and second pad regions extend in a first direction and form a step structure on the first connection region. The plurality of second dummy vertical structures are spaced apart from the first and second pad regions.

In additional embodiments, an integrated circuit memory device is provided that includes a stack structure on a semiconductor substrate. The stack structure includes a first gate stack group, which includes a plurality of spaced-apart first gate electrodes, and a second gate stack group, which includes a plurality of spaced-apart second gate electrodes. The second gate stack group extends on the first gate stack group so that the first gate stack group extends between the second gate stack group and the substrate. A plurality of channel structures are provided on the memory cell region, which penetrate vertically through the second gate stack group (as upper channel structures) and penetrate through the first gate stack group (as lower channel structures). A plurality of dummy channel structures are provided, which penetrate vertically through the second gate stack group but not through the first gate stack group. A plurality of dummy channel structures are also provided that penetrate vertically through the second gate stack group and through the first gate stack group.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of an integrated circuit/semiconductor device according to example embodiments;

FIGS. 2A and 2B are partially enlarged plan views illustrating an integrated circuit device according to example embodiments;

FIGS. 3A and 3B are schematic cross-sectional views of an integrated circuit device according to example embodiments;

FIG. 4 is a schematic cross-sectional view of an integrated circuit device according to example embodiments;

FIGS. 5 and 6 are partially enlarged cross-sectional views illustrating an integrated circuit device according to example embodiments;

FIG. 7 is a schematic cross-sectional view of an integrated circuit device according to example embodiments;

FIG. 8 is a partially enlarged cross-sectional view illustrating an integrated circuit device according to example embodiments;

FIGS. 9A to 9C are schematic cross-sectional views of integrated circuit devices according to example embodiments;

FIG. 10 is a schematic cross-sectional view of an integrated circuit device according to example embodiments;

FIGS. 11A to 11D are diagrams illustrating a method of manufacturing an integrated circuit device according to example embodiments;

FIGS. 12 to 16C are diagrams illustrating a method of manufacturing an integrated circuit device according to example embodiments;

FIG. 17 is a diagram schematically illustrating a data storage system including an integrated circuit device according to example embodiments;

FIG. 18 is a perspective view schematically illustrating a data storage system including an integrated circuit device according to an example embodiment; and

FIG. 19 is a cross-sectional view schematically illustrating an integrated circuit device according to an example embodiment.

### DETAILED DESCRIPTION

Hereinafter, example embodiments of the present inventive concept will be described with reference to the accompanying drawings.

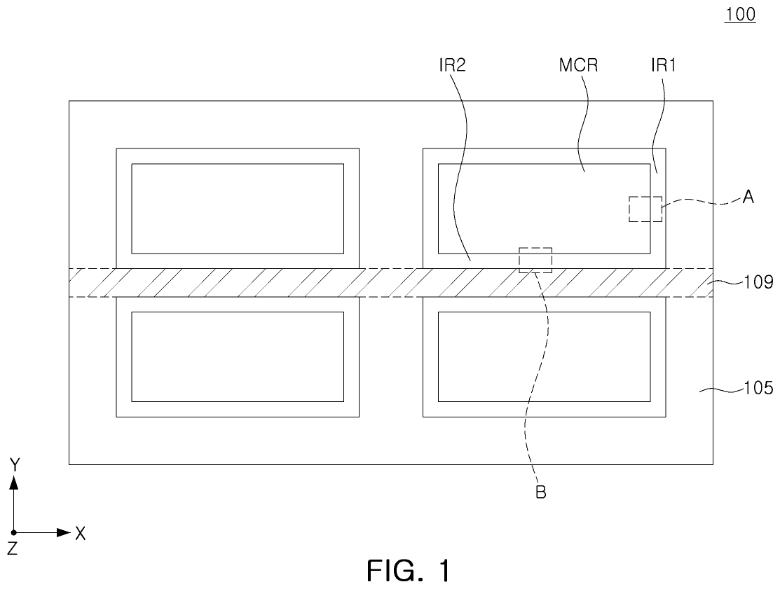

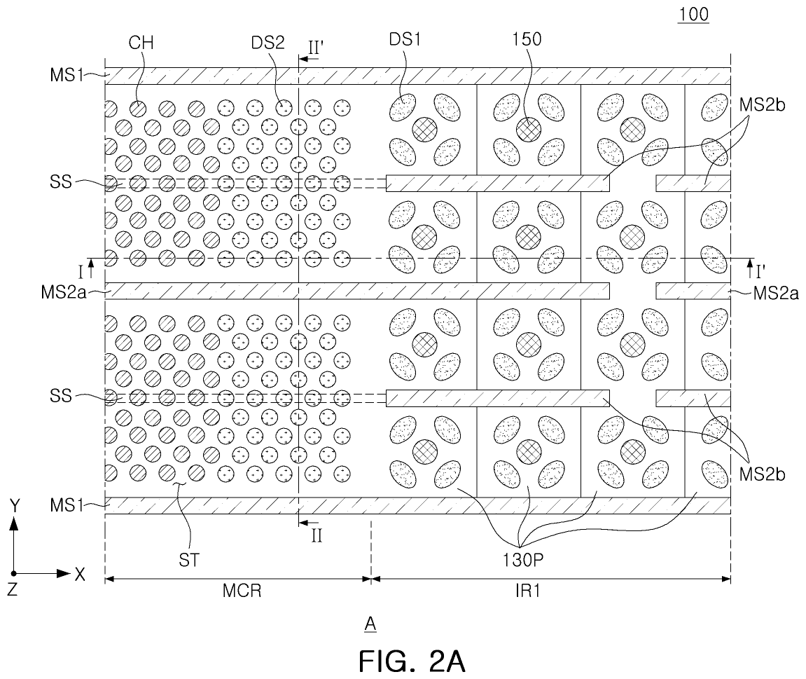

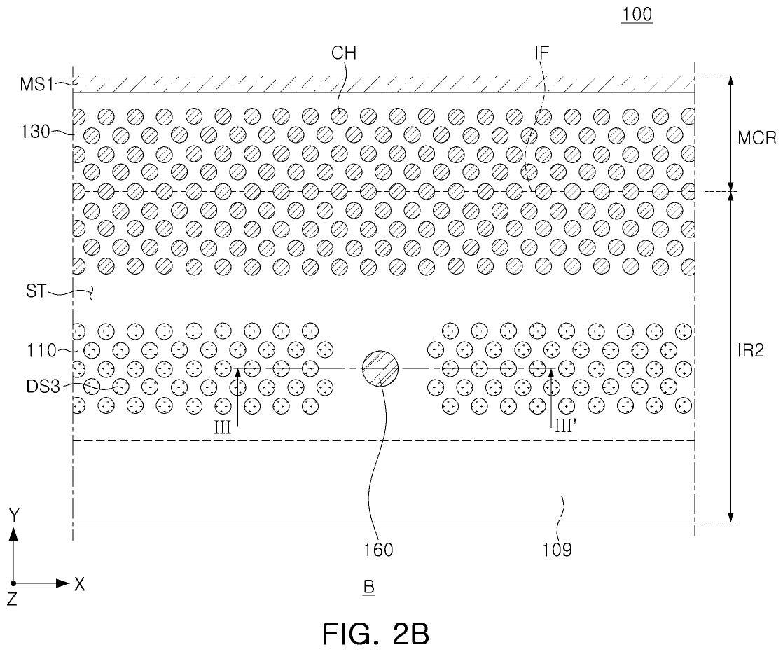

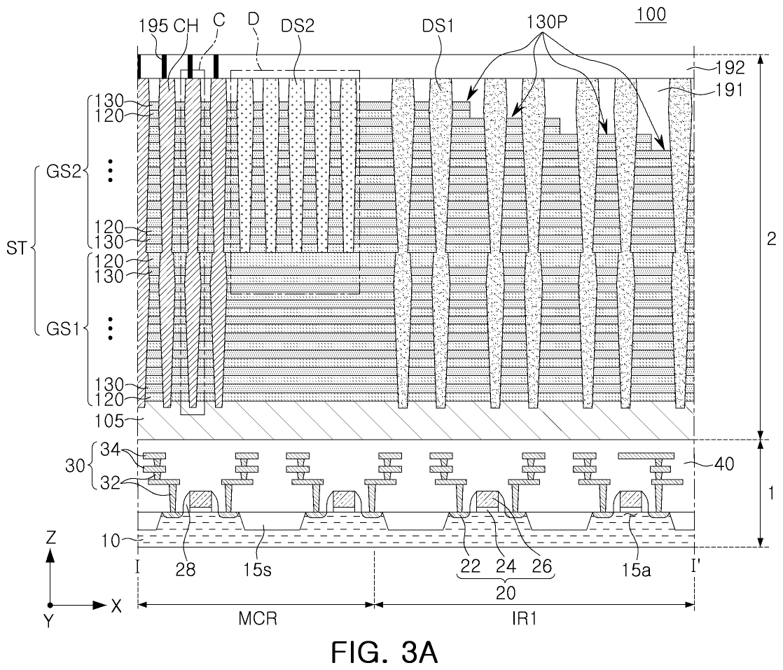

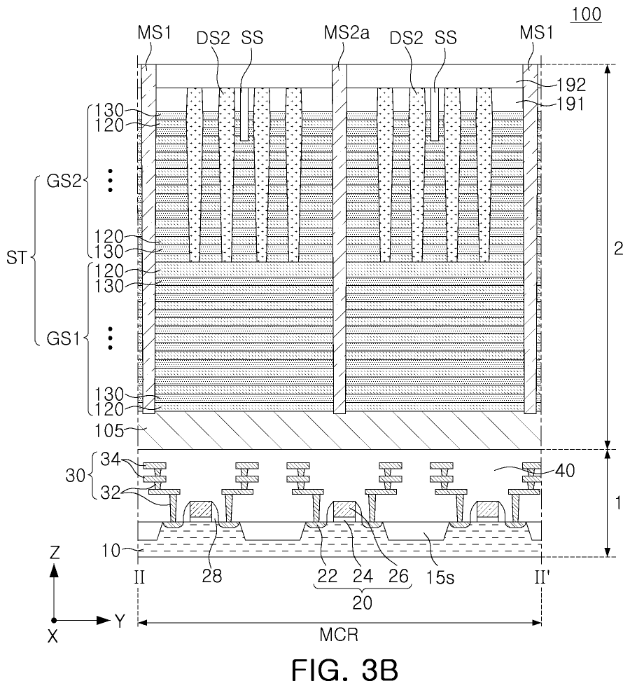

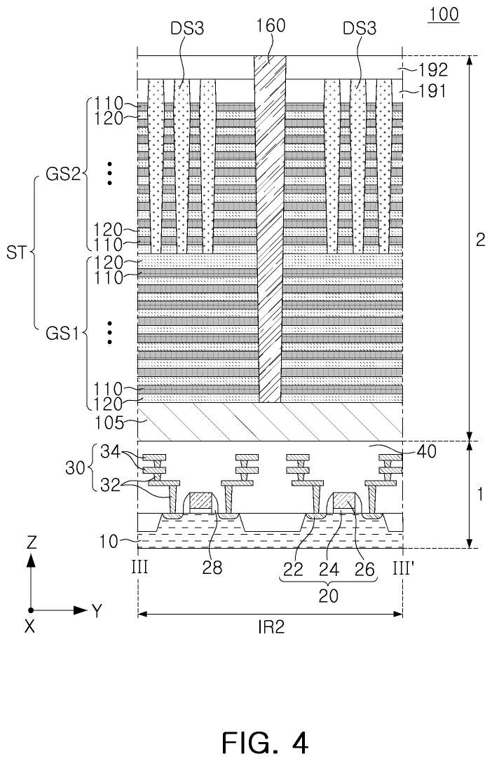

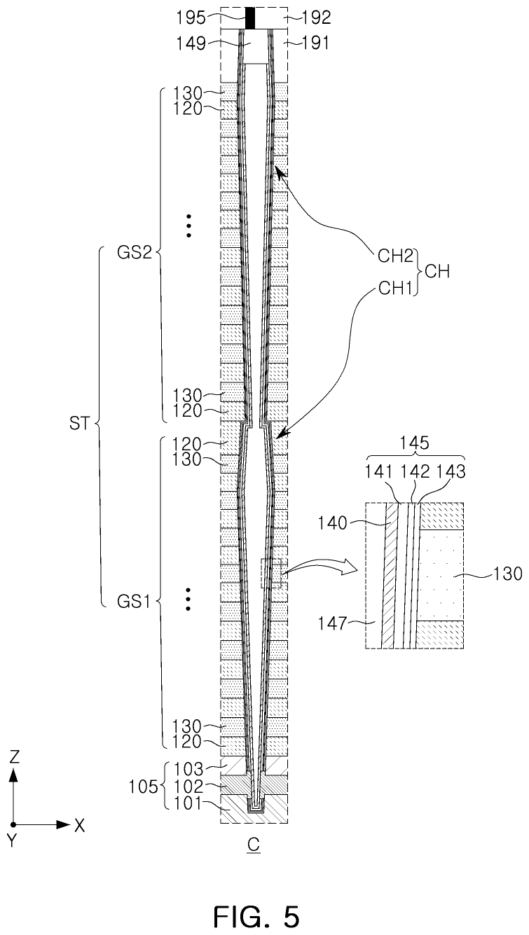

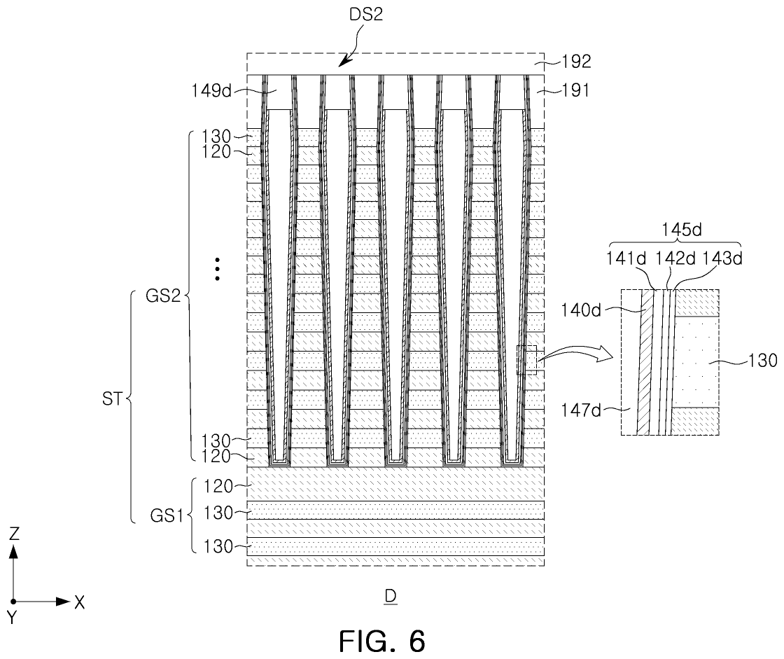

FIG. 1 is a schematic plan layout view of a semiconductor device according to example embodiments; and FIGS. 2A and 2B are partially enlarged plan layout views illustrating a semiconductor device according to example embodiments. In particular, FIG. 2A is an enlarged view of region ‘A’ of FIG. 1, and FIG. 2B is an enlarged view of region ‘B’ of FIG. 1. FIGS. 3A and 3B are schematic cross-sectional views of a semiconductor device according to example embodiments. FIG. 3A illustrates a cross-section of the semiconductor device of FIG. 2A taken along line I-I′, and FIG. 3B illustrates a cross-section of the semiconductor device of FIG. 2A taken along line II-II′. FIG. 4 is a schematic cross-sectional view of a semiconductor device according to example embodiments. In particular, FIG. 4 illustrates a cross-section taken along line III-III′ of FIG. 2B. FIGS. 5 and 6 are partially enlarged cross-sectional views illustrating a semiconductor device according to example embodiments. In particular, FIG. 5 is an enlarged view of region ‘C’ of FIG. 3A, whereas FIG. 6 is an enlarged view of region ‘D’ of FIG. 3A.

Referring to FIGS. 1 to 6, a semiconductor device 100 may include a first structure 1 and a second structure 2. The second structure 2 may be disposed on the first structure 1, which extends between the second structure 2 and an underlying supporting substrate. The first structure 1 is a region in which a peripheral circuit region of the semiconductor device 100 is disposed, and includes a row decoder, a page buffer, and other peripheral circuits. The second structure 2 is a region in which memory cells of the semiconductor device 100 are disposed, and includes gate electrodes 130 and channel layers 140.

The first structure 1 may include a substrate 10, device isolation layers 15s defining an active region 15a on the substrate 10, circuit elements 20 disposed on the substrate 10, a lower interconnection structure 30 electrically connected to the circuit elements 20, and a lower capping layer 40. The substrate 10 may include a semiconductor material, such as a group IV semiconductor, a group III-V compound semiconductor, or a group II-VI compound semiconductor. The substrate 10 may be provided as a bulk wafer or as an epitaxial layer on an underlying substrate layer. The device isolation layers 15s may be disposed in the substrate 10, and source/drain regions 22 including impurities may be disposed in a portion of the active region 15a.

The circuit elements 20 may each include a transistor including the source/drain region 22, a circuit gate dielectric layer 24, and a circuit gate electrode 26. The source/drain regions 22 may be disposed on both sides of the circuit gate electrode 26, in the active region 15a. The circuit gate dielectric layer 24 may be disposed between the active region 15a and the circuit gate electrode 26. Spacer layers 28 may be disposed on both sides of the circuit gate electrode 26. The circuit gate electrode 26 may include a material layer such as, for example, tungsten (VV), titanium (Ti), tantalum (Ta), tungsten nitride (WN), titanium nitride (TiN), tantalum nitride (TaN), polycrystalline silicon, or a metal-semiconductor compound.

The lower interconnection structure 30 may be electrically connected to the circuit elements 20. The lower interconnection structure 30 may include a lower contact 32 and a lower interconnection 34. A portion of the lower contacts 32 may extend “vertically” in the Z-direction to be connected to the source/drain regions 22. The lower contact 32 may electrically connect the lower interconnections 34 disposed on different levels to each other. The lower interconnection structure 30 may include a conductive material, for example, a metal material such as tungsten (W), titanium (Ti), tantalum (Ta), copper (Cu), aluminum (Al), molybdenum (Mo), or ruthenium (Ru). A barrier layer formed of a metal nitride such as tungsten nitride (WN) or titanium nitride (TiN) may be disposed on the bottom and side surfaces of the lower interconnection structure 30. The number of layers and the arrangement of the lower contacts 32 and the lower interconnection 34 constituting the lower interconnection structure 30 may be variously changed. At least a portion of the lower interconnections 34 may include a pad layer to which a plurality of through-contact structures extending downwardly from the second structure 2 are directly connected.

The lower electrically insulating capping layer 40 may be disposed to cover the substrate 10, the circuit devices 20, and the lower interconnection structure 30, and act as a passivation and planarization layer. The lower capping layer 40 may be formed of an insulating material such as silicon oxide or silicon nitride, and may include a plurality of insulating layers. The lower capping layer 40 may include an etch stop layer formed of silicon nitride.

The second structure 2 may include an “elevated” and laterally extending source structure 105, a stack structure ST on the source structure 105, separation structures MS1, MS2a and MS2b penetrating through the stack structure ST and extending in the X-direction, channel structures CH passing through the stack structure ST and including the channel layer 140, and dummy vertical channel structures DS1, DS2, and DS3 passing through at least a portion of the stack structure ST. The second structure 2 may further include sacrificial layers 110 and interlayer insulating layers 120 that form a portion of the stack structure ST, an upper separation structure SS passing through a portion of the upper gate electrodes 130, a gate contact structure 150 connected to the gate electrodes 130, a source contact structure 160 connected to the source structure 105, upper capping layers 191 and 192, and a contact plug 195.

The source structure 105 may be disposed on the first structure 1. At least a portion of the source structure 105 may be formed of, for example, polycrystalline silicon having an N-type conductivity. In the source structure 105, a region formed of polycrystalline silicon having an N-type conductivity may be a common source region. As illustrated in FIG. 1, the source structure 105 may have a shape partially divided in the Y-direction by the lower insulating layer 109 extending in the X-direction.

As an example, referring to FIG. 5, the source structure 105 may include a conductive plate layer 101, and a first patterned layer 102 and a second patterned layer 103 on the conductive plate layer 101. The first patterned layer 102 may penetrate through the gate dielectric layer 145 and contact the channel layer 140. At least one of the conductive plate layer 101, the first pattern layer 102, and the second pattern layer 103 may include silicon. For example, the source structure 105 may include at least one of doped polycrystalline silicon, a metal, and a metal-semiconductor compound. As an example, the source structure 105 may be formed of a single layer, for example, a silicon layer.

The source structure 105 may include a memory cell region MCR and connection regions IR1 and IR2. The connection regions IR1 and IR2 may surround the memory cell region MCR. The connection regions IR1 and IR2 may include a first region IR1 in which the gate contact structure 150 is disposed and a second region IR2 in which the source contact structure 160 is disposed.

The stack structure ST may be disposed on the source structure 105. The stack structure ST may include a first stack group GS1 and a second stack group GS2 disposed on the first stack group GS1.

The first stack group GS1 may include first interlayer insulating layers 120 and first gate electrodes 130 that are alternately stacked, and the second stack group GS2 may include second interlayer insulating layers 120 and second gate electrodes 130 that are alternately stacked. The first gate electrodes 130 may include a first gate stack group, and the second gate electrodes 130 may include a second gate stack group.

On the second connection region IR2, the first stack group GS1 may further include first sacrificial layers 110 disposed on substantially the same level as the first gate electrodes 130, and the second stack group GS2 may further include second sacrificial layers 110 disposed on substantially the same level as the second gate electrodes 130. The first sacrificial layers 110 may include a first sacrificial stack group, and the second sacrificial layers 110 may include a second sacrificial stack group.

The gate electrodes 130 may be stacked to be spaced apart from each other in the Z-direction on the source structure 105 in the memory cell region MCR. The gate electrodes 130 may extend in the X-direction, and may provide pad regions 130P having a stepped structure on the first connection region IR1. The gate electrodes 130 may include lower gate electrodes forming the gate of the ground select transistor, memory gate electrodes forming the plurality of memory cells, and upper gate electrodes forming the gates of the string select transistors. The number of the memory gate electrodes constituting the memory cells may be determined according to the capacity of the semiconductor device 100. In example embodiments, the gate electrodes 130 may further include a gate electrode constituting the erase transistor, disposed on the upper gate electrodes and/or below the lower gate electrodes and used for an erase operation using a gate induced drain leakage (GIDL) phenomenon.

The gate electrodes 130 are vertically spaced apart and stacked on the source structure 105, and although not illustrated, may extend to different lengths in the Y-direction to form a stepped structure in the form of a step. Due to the step structure, the gate electrodes 130 may have pad regions 130P in which the lower gate electrode 130 extends longer than the upper gate electrode 130 and is exposed upwardly, and may be disposed on the pad regions 130P. In this specification, the pad regions may be used as terms referring to the entire region in which the gate electrodes 130 form step-shaped structure on the first connection region IR1.

The gate electrodes 130 may be disposed to be separated from each other in a predetermined unit in the Y-direction by the first separation structures MS1 extending in the X-direction. The gate electrodes 130 between the pair of separation structures MS1 may form one memory block, but the scope of the memory block is not limited thereto.

The gate electrodes 130 may each include a first layer and a second layer. The first layer may cover upper and lower surfaces of the second layer and may extend between the channel structure CH and the second layer. The first layer may include a high dielectric material such as aluminum oxide (AlO) or the like, and the second layer may include at least one of titanium (Ti), titanium nitride (TiN), tantalum (Ta), tantalum nitride (TaN), tungsten (W), and tungsten nitride (WN). In some embodiments, the gate electrodes 130 may include polycrystalline silicon or a metal-semiconductor compound.

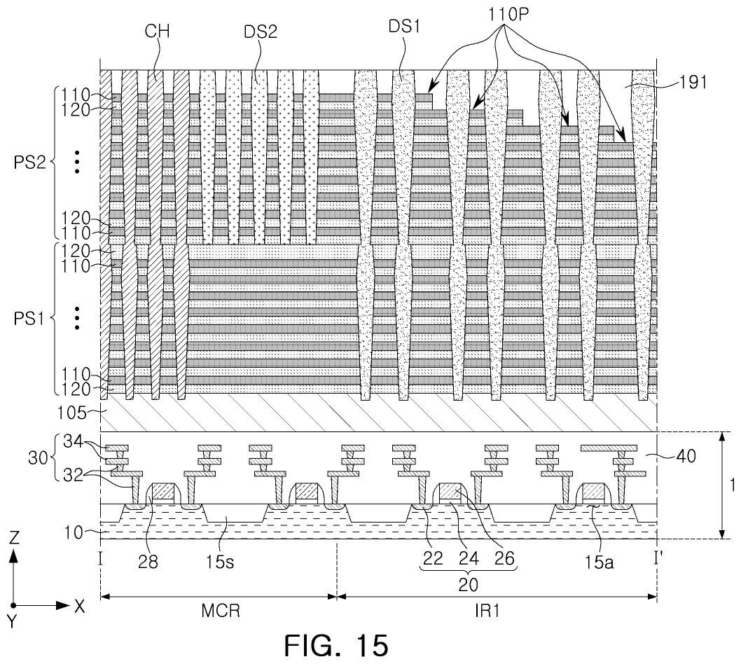

The sacrificial layers 110 may be positioned on substantially the same level as the gate electrodes 130, on the second connection region IR2. The sacrificial layers 110 may electrically insulate the gate electrodes 130 from the source contact structure 160. The sacrificial layers 110 may include an insulating material such as silicon nitride. The sacrificial layers 110 may have side surfaces contacting side surfaces of the gate electrodes 130 (refer to IF of FIG. 2B). In a process operation of removing the sacrificial layers 110 through separation openings (‘OP’ in FIG. 15B), a portion of the sacrificial layers 110 may remain on the second connection region IR2 without being removed.

The interlayer insulating layers 120 may be disposed between the gate electrodes 130 and form the stack structure ST. The interlayer insulating layers 120 may be disposed between the gate electrodes 130, on the memory cell region MCR and the first connection region IR1, and extend onto the second connection region IR2 to form the sacrificial layers 110. Like the gate electrodes 130, the interlayer insulating layers 120 may be spaced apart from each other in the Z-direction and may be disposed to extend in the X-direction. The interlayer insulating layers 120 may include an insulating material such as silicon oxide. Portions of the interlayer insulating layers 120 may have different thicknesses.

The separation structures MS1, MS2a, and MS2b may extend in the X-direction on the memory cell region MCR and the first connection region IR1 and may be disposed parallel to each other. The separation structures MS1, MS2a, and MS2b may pass through the stack structure ST and may contact the source structure 105. Each of the separation structures MS1, MS2a, and MS2b may include at least one of silicon oxide, silicon nitride, and silicon oxynitride. Each of the separation structures MS1, MS2a, and MS2b may include a plurality of insulating layers, or may include a core pattern including a conductive material and an isolation pattern covering side surfaces and a bottom surface of the core pattern and including an insulating material. The separation structures MS1, MS2a, and MS2b may include a first separation structure MS1 and second separation structures MS2a and MS2b.

The second separation structures MS2a and MS2b may include a second central separation structure MS2a disposed to be spaced apart from each other by a predetermined distance in the Y-direction, between the pair of first separation structures MS1, and a second auxiliary separation structure MS2b disposed to be spaced apart from each other by a predetermined distance in the Y-direction, between the first separation structure MS1 and the second central separation structure MS2a and between the second central separation structures MS2a. The second central separation structure MS2a may be disposed throughout the memory cell region MCR and the first connection region IR1. The second central separation structure MS2a may extend as one, from the memory cell region MCR to a portion of the first connection region IR1, and may be spaced apart from the second central separation structure MS2a in the X-direction, on the first connection region IR1, to extend again as one. The second auxiliary separation structure MS2b may be disposed only on the first connection region IR1, and may be disposed as a plurality of second auxiliary separation structures MS2b separated from each other at predetermined intervals on a straight line.

The upper separation structures SS may extend in the X-direction between the separation structures MS1 and MS2a. The upper separation structures SS may separate some of the upper gate electrodes 130 among the gate electrodes 130 from each other in the Y-direction. However, the number of gate electrodes 130 separated by the upper separation structures SS may be changed in other example embodiments. The upper gate electrodes 130 separated by the upper separation structures SS may form different string select lines. The upper separation structures SS may include an insulating material, for example, silicon oxide, silicon nitride, or silicon oxynitride.

As illustrated in FIG. 2A, the channel structures CH may each form one memory cell string, and may be disposed to be spaced apart from each other while forming rows and columns in the memory cell region MCR. The channel structures CH may be disposed to form a grid pattern or may be disposed in a zigzag shape in one direction. The channel structures CH may have a columnar shape, and may have inclined side surfaces that are narrower in width closer to the source structure 105 according to an aspect ratio.

A channel layer 140 may be disposed in the channel structures CH. In the channel structures CH, the channel layer 140 may be formed in an annular shape surrounding the inner core insulating layer 147. As illustrated in FIG. 5, the channel layer 140 may be in contact with the first pattern layer 102 and may be electrically connected to the conductive plate layer 101. The channel layer 140 may include a semiconductor material such as polycrystalline silicon or monocrystalline silicon.

A channel pad 149 may be disposed on the channel layer 140 in the channel structures CH. The channel pad 149 may be disposed to cover the upper surface of the core insulating layer 147 and be electrically connected to the channel layer 140. The channel pad 149 may include a semiconductor material such as polycrystalline silicon or single crystal silicon, for example, may include doped polycrystalline silicon. A contact plug 195 may be disposed on the channel pad 149, and the contact plug 195 may be electrically connected to upper interconnections including bit lines.

The gate dielectric layer 145 may be disposed between the gate electrodes 130 and the channel layer 140. The gate dielectric layer 145 may include a tunneling layer 141, an information storage layer 142, and a blocking layer 143 sequentially stacked from the channel layer 140. The tunneling layer 141 may tunnel charges into the information storage layer 142, and may include, for example, silicon oxide, silicon nitride, silicon oxynitride, or combinations thereof. The information storage layer 142 may be a charge trap layer or a floating gate conductive layer. The blocking layer 143 may include silicon oxide, silicon nitride, silicon oxynitride, a high-k dielectric material, or combinations thereof. In example embodiments, at least a portion of the gate dielectric layer 145 may extend in a horizontal direction along the gate electrodes 130.

As illustrated in FIG. 5, the channel structures CH may penetrate through the entire gate electrodes 130 of the stack structure ST in the Z-direction, and may penetrate through the first pattern layer 102 and the second pattern layer 103 in the Z-direction to be partially extended into the conductive plate layer 101. The first pattern layer 102 may penetrate through the gate dielectric layer 145, below the stack structure ST, to contact the channel layer 140. The first pattern layer 102 may be directly connected to the channel layer 140, around the channel layer 140.

As illustrated in FIG. 5, each of the channel structures CH may include a lower channel structure CH1 passing through the first gate stack group of the first stack group GS1, and an upper channel structure CH2 passing through the second gate stack group of the second stack group GS. Each of the channel structures CH may include a bent portion due to a difference between the width of the upper end of the lower channel structure CH1 and the width of the upper end of the upper channel structure CH2. The channel layer 140 of the lower channel structure CH1 and the channel layer 140 of the upper channel structure CH2 may be connected as one.

Among the channel structures CH, the channel structures CH disposed in the memory cell region MCA adjacent to the second connection region IR2 may be dummy channels. In addition, the channel structures CH disposed to overlap the upper separation structures SS among the channel structures CH may also be dummy channels.

The dummy vertical channel structures DS1, DS2, and DS3 may include first dummy vertical channel structures DS1, second dummy vertical channel structures DS2, and third dummy vertical channel structures DS3. The second dummy vertical channel structure DS2 may be referred to as the third dummy vertical channel structure, and the third dummy vertical channel structure DS3 may be referred to as the second dummy vertical channel structure.

As illustrated in FIG. 2A, the first dummy vertical channel structures DS1 may pass through the stack structure ST, on the first connection region IR1. For example, the first dummy vertical channel structures DS1 may penetrate through the pad regions 130P of the gate electrodes 130 as illustrated in FIG. 3A. The first dummy vertical channel structures DS1 may be disposed to be spaced apart from each other in rows and columns, similar to the channel structures CH, and may be disposed to form a grid pattern or disposed in a zigzag shape in one direction. The first dummy vertical channel structures DS1 may have the same or similar structure to the channel structures CH, but may not perform a substantial function during the operation of the semiconductor device 100. The first dummy vertical channel structures DS1 may serve as supports for supporting the stack structure ST, on the first connection region IR1. The arrangement of the first dummy vertical channel structures DS1 may be variously changed according to example embodiments.

The second dummy vertical channel structures DS2 may be disposed on the memory cell region MCR and may be disposed between the channel structures CH and the first dummy vertical channel structures DS1. For example, the second dummy vertical channel structures DS2 may be formed on one edge region of the memory cell region MCR adjacent to the first connection region IR1. The second dummy vertical channel structures DS2 may penetrate through all the second gate electrodes 130 of the second stack group GS2, on the first stack group GS1. The second dummy vertical channel structures DS2 may penetrate through an uppermost second gate electrode 130 among the second gate electrodes 130 of the second stack group GS2. Lower ends of the second dummy vertical channel structures DS2 may be disposed on a level higher than at least one of the first gate electrodes 130 of the first stack group GS1. The second dummy vertical channel structures DS2 may be spaced apart from the first gate electrodes 130 of the first stack group GS1 and may also be spaced apart from the pad regions 130P of the gate electrodes 130.

As illustrated in FIG. 6, each of the second dummy vertical channel structures DS2 may include a dummy gate dielectric layer 145d, a dummy channel layer 140d, a dummy core insulating layer 147d, and a dummy channel pad 149d. The dummy gate dielectric layer 145d may include a first dielectric layer 141d, a second dielectric layer 142d, and a third dielectric layer 143d sequentially stacked from the dummy channel layer 140d. The first dielectric layer 141d may correspond to the tunneling layer 141, the second dielectric layer 142d may correspond to the information storage layer 142, and the third dielectric layer 143d may correspond to the blocking layer 143. Each of the first dummy vertical channel structures DS1 and the third dummy vertical channel structures DS3 may have a structure similar to the structure of the second dummy vertical channel structures DS2.

The third dummy vertical channel structures DS3 may be disposed on the second connection region IR2. The third dummy vertical channel structures DS3 may penetrate through all the second sacrificial layers 110 of the second stack group GS2, on the first stack group GS1, and may be spaced apart from the first sacrificial layers 110 of the first stack group GS1. Lower ends of the third dummy vertical channel structures DS3 may be disposed on a level higher than at least one of the first sacrificial layers 110 of the first stack group GS1. The third dummy vertical channel structures DS3 may be spaced apart from the first sacrificial layers 110 of the first stack group GS1. A source contact structure 160 may be disposed between the third dummy vertical channel structures DS3.

According to an example of the present inventive concept, since the semiconductor device 100 includes the second dummy vertical channel structures DS2 and the third dummy vertical channel structures DS3, reliability of the integrated circuit semiconductor device may be improved. Moreover, when the stack structure ST is disposed in two or more stages, the sacrificial layer disposed in the lower vertical hole is exposed and removed by the upper vertical hole. However, in a case in which the etch depth of the upper vertical hole does not reach the upper end of the lower vertical hole, the sacrificial layer is unstripped, thereby causing a defect in the semiconductor device. Such an unstrip defect mainly occurs in an edge region of a region in which the hole patterns are disposed. According to an example of the present inventive concept, since the sacrificial layer and the lower vertical hole penetrating through the first stack group GS1 are not formed below the second dummy vertical channel structures DS2 and the third dummy vertical channel structures DS3, an “unstripping” defect of the sacrificial layer may be prevented from occurring.

As illustrated in FIG. 2A, the gate contact structure 150 may be disposed on the first connection region IR1 to be connected to the pad regions 130P of the gate electrodes 130. The gate contact structure 150 may have a pillar shape, and may have inclined side surfaces that are narrower in width closer to the gate electrodes 130 according to an aspect ratio. The gate contact structure 150 may be disposed in plural, and may be electrically connected to the circuit elements 20 of the first structure 1 through separate interconnection and through-plugs.

As illustrated in FIG. 2B, the source contact structure 160 may be disposed on the second connection region IR2, to penetrate through the first sacrificial layers 110 of the first stack group GS1 and the second sacrificial layers 110 of the second stack group GS2 and to be connected to the source structure 105. The source contact structure 160 may be in contact with the source structure 105 or may be disposed by partially recessing the source structure 105. The source contact structure 160 may have a columnar shape, and may have an inclined side surface narrowing as it approaches the source structure 105 according to an aspect ratio. The upper capping layers 191 and 192 may cover the stack structure ST. The upper capping layers 191 and 192 may be formed of an insulating material such as silicon oxide or silicon nitride. The upper capping layers 191 and 192 may include a plurality of insulating layers.

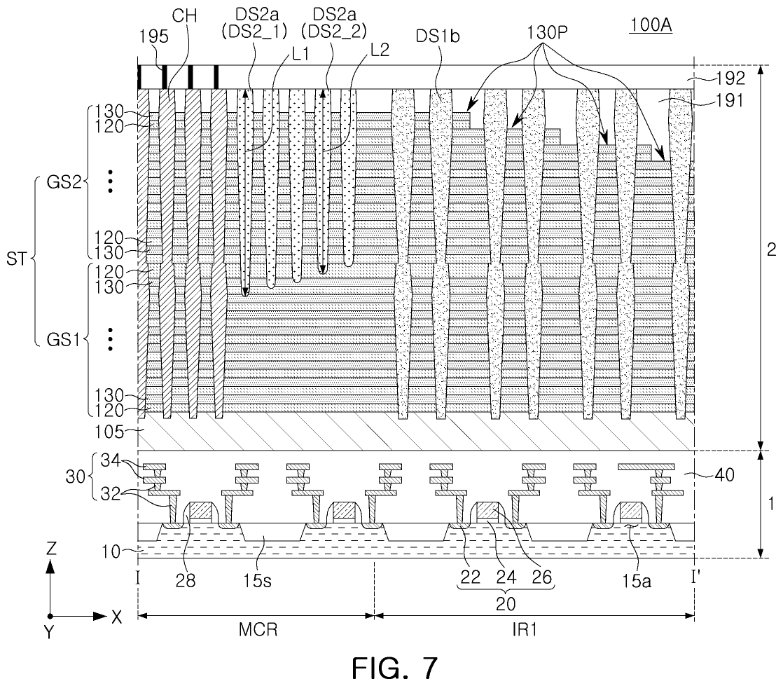

FIG. 7 is a schematic cross-sectional view of a semiconductor device according to example embodiments. FIG. 7 illustrates a region corresponding to FIG. 3A. Referring to FIG. 7, in a semiconductor device 100A, the depths of lower ends of the second dummy vertical channel structures DS2a may be different from each other. For example, the second dummy vertical channel structures DS2a may include a first vertical pattern DS2_1 and a second vertical pattern DS2_2, and the first vertical pattern DS2_1 may be disposed closer to the channel structures CH than the second vertical pattern DS2_2, and a vertical length L1 of the first vertical pattern DS2_1 may be greater than a vertical length L2 of the second vertical pattern DS2_2. For example, the vertical length of the second dummy vertical channel structures DS2a may be reduced closer to the first connection region IR1.

Since the second dummy vertical channel structures DS2a do not land on the sacrificial layer of the lower vertical hole, at least a portion of the second dummy vertical channel structures DS2a may come into contact with a portion of the first gate electrodes 130 of the first stack group GS1. A lower portion of the second dummy vertical channel structures DS2a may have a downwardly pointed or rounded shape. According to example embodiments, the lower end depth or lower shape of the second dummy vertical channel structures DS2a may be variously changed.

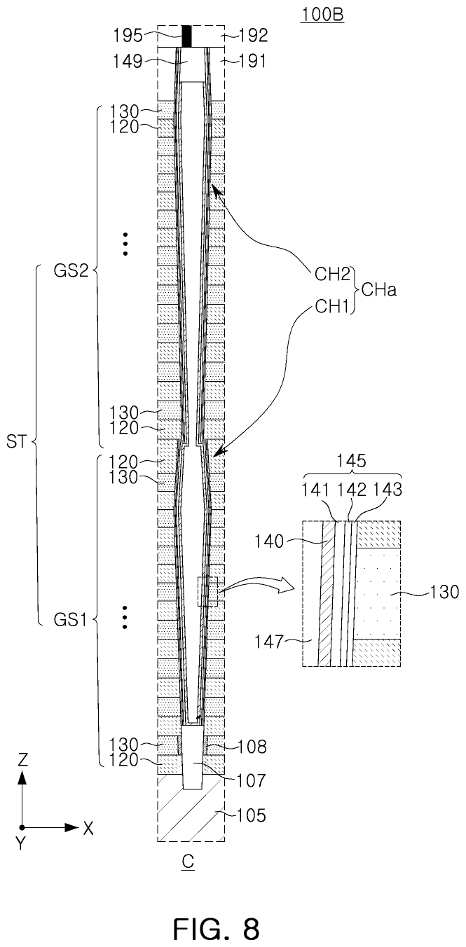

FIG. 8 is a partially enlarged cross-sectional view illustrating a semiconductor device according to example embodiments; FIG. 8 illustrates a region corresponding to FIG. 5. Referring to FIG. 8, in a semiconductor device 1006, the source structure 105 does not include the first pattern layer 102 and the second pattern layer 103, but is formed of a single silicon layer, and each of the channel structures Cha may include an epitaxial layer 107 in contact with the lower portion of the channel layer 140. The epitaxial layer 107 may be connected to the source structure 105. The epitaxial layer 107 may be formed using a selective epitaxial growth (SEG) process. The epitaxial layer 107 may be formed of a single layer or a plurality of layers. The epitaxial layer 107 may include polycrystalline silicon, single crystal silicon, polycrystalline germanium, or single crystal germanium doped or undoped with impurities. An insulating layer 108 may be disposed between the epitaxial layer 107 and a lowermost gate electrode 130.

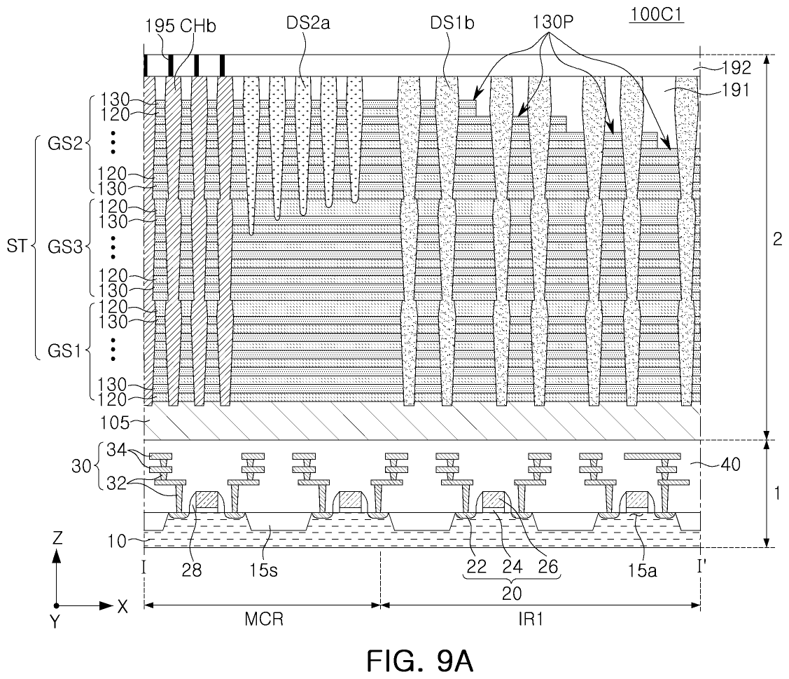

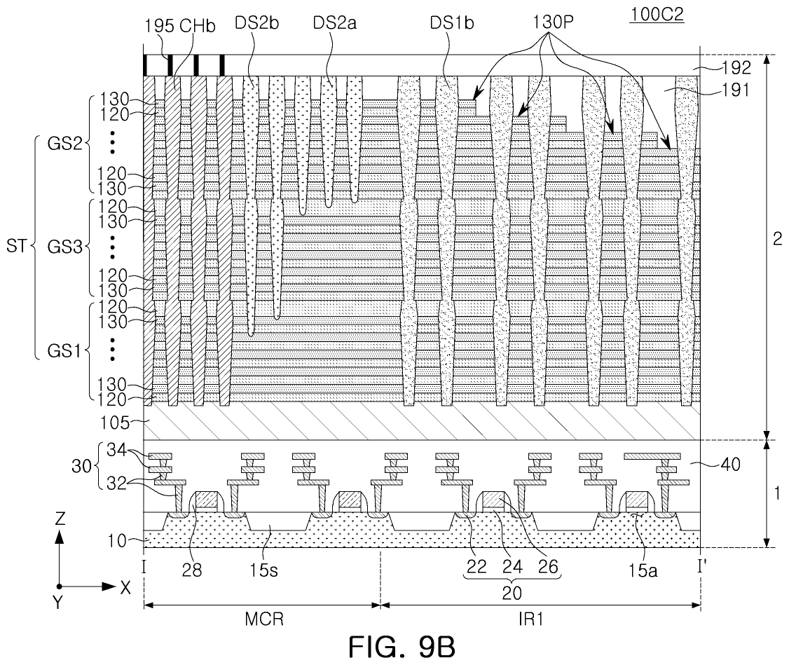

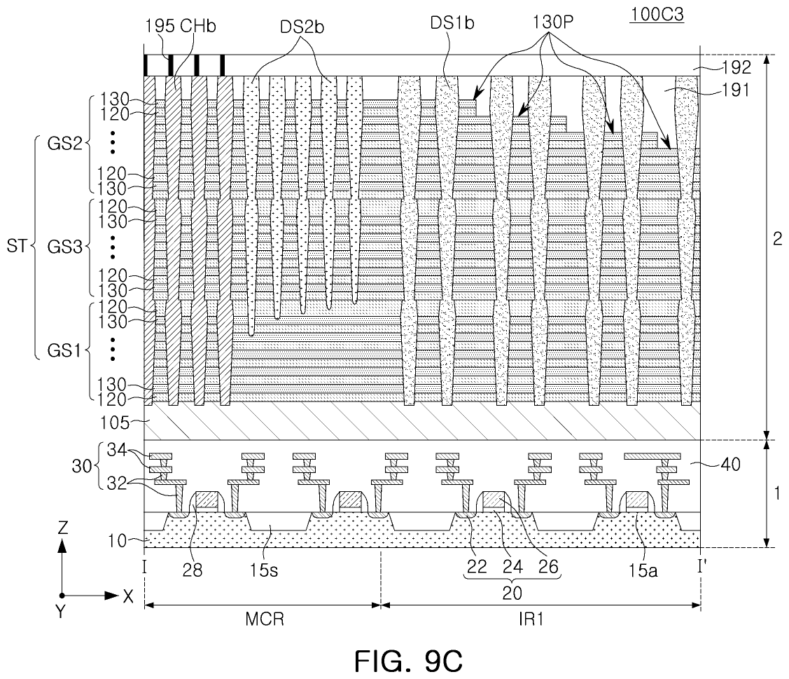

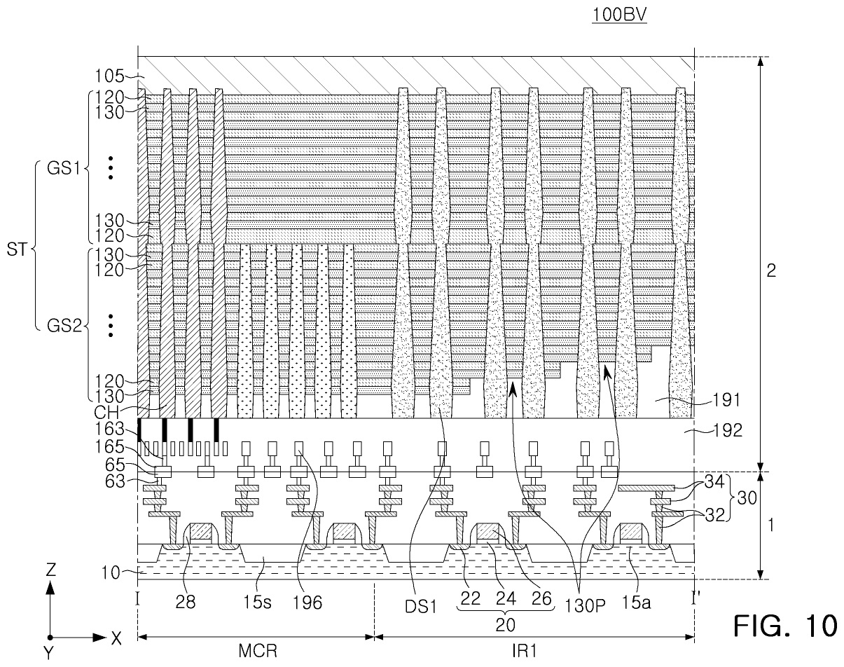

FIGS. 9A to 9C are schematic cross-sectional views of semiconductor devices according to example embodiments. Referring to FIGS. 9A to 9C, the stack structure ST may further include a third stack group GS3 between the first stack group GS1 and the second stack group GS2, and the third stack group GS3 may include third interlayer insulating layers 120 and third gate electrodes 130 that are alternately stacked. The third gate electrodes 130 may include a third gate stack group. Accordingly, each of the channel structures CHb may also include an intermediate channel structure between the lower channel structure and the upper channel structure, and the intermediate channel structure may pass through the third stack group GS3. Each of the channel structures CHb may include a first bent portion between the first stack group GS1 and the third stack group GS3 and a second bent portion between the second stack group GS2 and the third stack group GS3. The first dummy vertical channel structures DS1b may also have a structure similar to the structure of the channel structures CHb. The present embodiments illustrate a case in which the stack structure ST has a three-stack structure, and the present inventive concept may also include an example embodiment of a multi-stack structure.

Referring to FIG. 9A, in a semiconductor device 100C1, the second dummy vertical channel structures DS2a may extend to a portion of the third stack group GS3, and at least a portion of the second dummy vertical channel structures DS2a may contact at least a portion of the third gate electrodes 130 of the third stack group GS3. The vertical lengths of the second dummy vertical channel structures DS2a may decrease closer to the first connection region IR1 from the memory cell region MCR, but the present inventive concept is not limited thereto. Defects caused by unstripping of the sacrificial layer in the first and third stack groups GS1 and GS3 may be prevented.

Referring to FIG. 9B, in a semiconductor device 100C2, the second dummy vertical channel structures DS2b disposed relatively close to the channel structures CHb among the second dummy vertical channel structures DS2a and DS2b may include a lower pattern penetrating through the third stack group GS3 and an upper pattern penetrating through the second stack group GS2. The second dummy vertical channel structures DS2b may include a bent portion due to a difference between a width of an upper end of the lower pattern and a width of a lower end of the upper pattern. Defects due to unstripping of the sacrificial layer in the first stack group GS1 may be prevented below the second dummy vertical channel structures DS2b, and defects caused by unstripping of the sacrificial layer in the first and third stack groups GS1 and GS3 may be prevented below the second dummy vertical channel structures DS2a.

Referring to FIG. 9C, in a semiconductor device 100C3, each of the second dummy vertical channel structures DS2b may include a lower pattern passing through the third stack group GS3 and an upper pattern passing through the second stack group GS2. Each of the second dummy vertical channel structures DS2b may include a bent portion due to a difference between a width of an upper end of the lower pattern and a width of a lower end of the upper pattern. Defects caused by unstripping of the sacrificial layer in the first stack group GS1 below the second dummy vertical channel structures DS2b may be prevented.

FIG. 10 is a schematic cross-sectional view of a semiconductor device according to example embodiments. Referring to FIG. 10, a first structure 1 and a second structure 2 of a semiconductor device 100BV may be bonded to each other through a bonding structure without a separate adhesive layer. The second structure 2 is illustrated by vertically inverting the second structure 2 of the semiconductor device 100 of FIG. 3A.

The semiconductor device 100BV may further include an upper bonding pad 165 and a lower bonding pad 65. The upper bonding pad 165 may be electrically connected to the upper interconnection structure through a separate upper bonding via 163, and the lower bonding pad 65 may be electrically connected to the circuit elements 20 through a separate lower via 63. The lower bonding pad 65 and the upper bonding pad 165 may each include, for example, tungsten (W), aluminum (Al), copper (Cu), tungsten nitride (WN), tantalum nitride (TaN), titanium nitride (TiN), or combinations thereof. The lower bonding pad 65 and the upper bonding pad 165 may function as bonding layers for bonding the first structure 1 and the second structure 2. In addition, the lower bonding pad 65 and the upper bonding pad 165 may provide an electrical connection path between the first structure 1 and the second structure 2.

The lower bonding pad 65 and the upper bonding pad 165 may be bonded by copper-to-copper bonding. In addition to the copper-to-copper bonding, the first structure 1 and the second structure 2 may be bonded by dielectric-to-dielectric bonding. The dielectric-to-dielectric bonding may be bonding, for example, by dielectric layers forming a portion of each of the upper capping layer 192 and the lower capping layer 40 and surrounding the upper bonding pad 165 and the lower bonding pad 65.

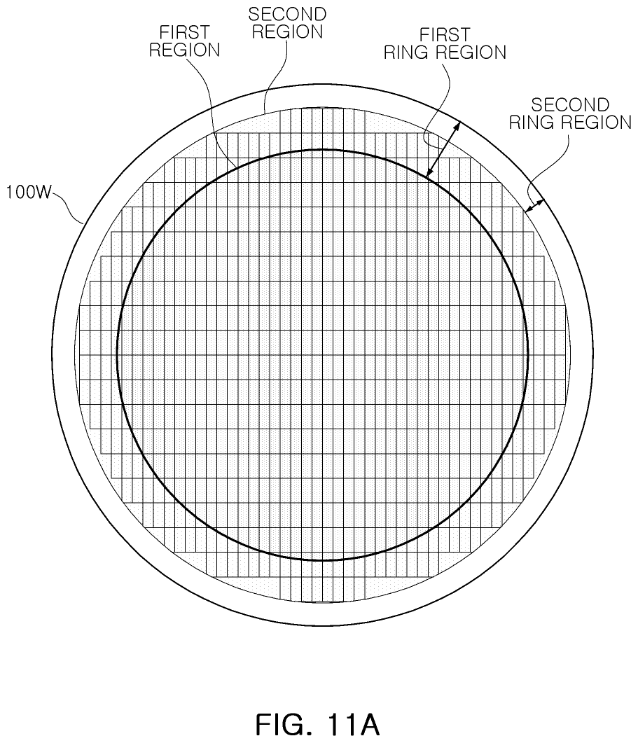

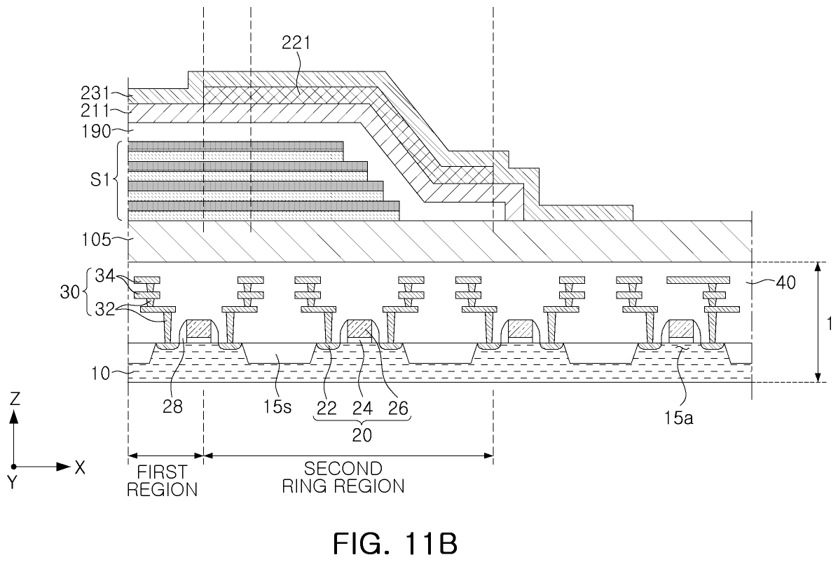

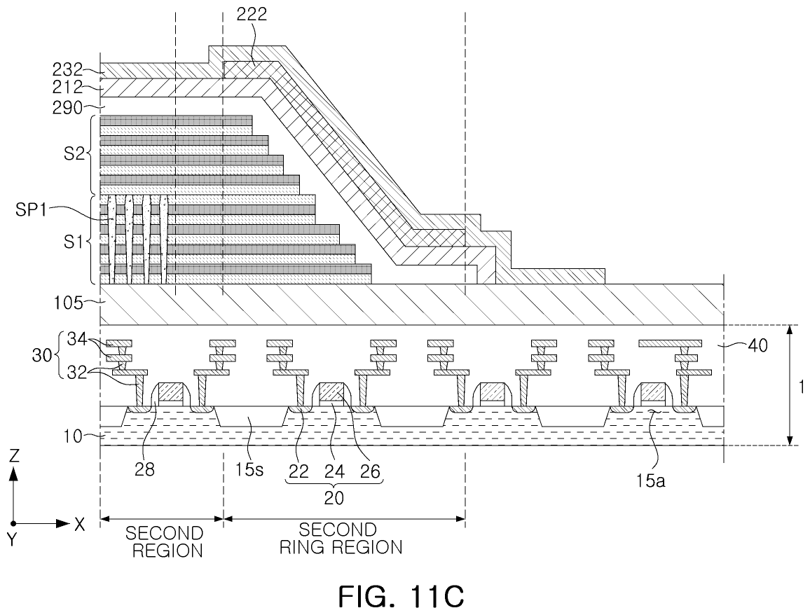

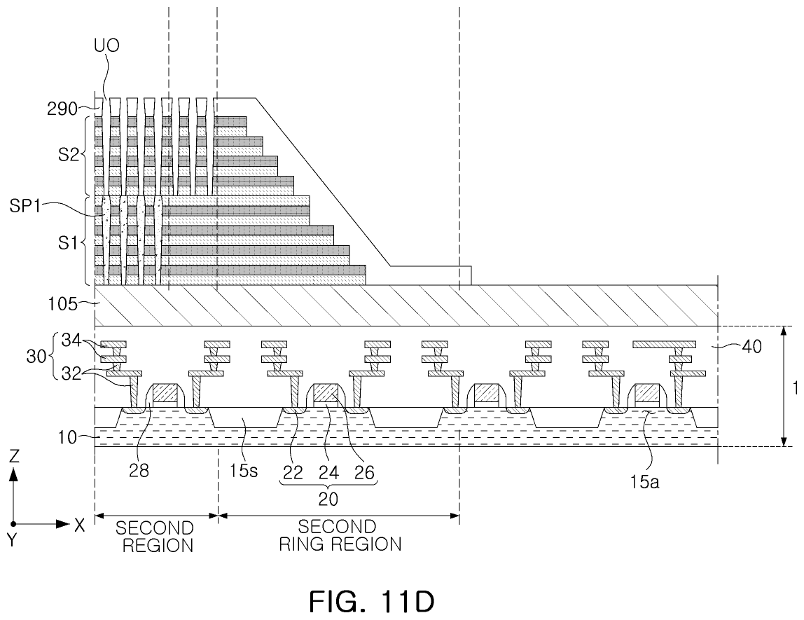

FIGS. 11A to 11D are diagrams illustrating a method of manufacturing a semiconductor device according to example embodiments. Referring to FIG. 11A, on a wafer 100W, a first photolithography process and a first etching process may be performed on a first region, and a second photolithography process and a second etching process may be performed on a second region.

The first region may have a smaller area than an area of the second region. The outer region of the first region may be a first ring region, and may be a region in which patterning is not performed during the first etching process. The outer region of the second region may be a second ring region, and may be a region in which patterning is not performed during the second etching process. For example, the first region may be a region in which lower hole patterns are formed, and the second region may be a region in which upper hole patterns are formed.

The wafer 100W may be a semiconductor wafer structure including a substrate 10, circuit elements 20, a source structure 105, and the like. As illustrated in FIGS. 11B to 11D, sacrificial layers SP1 may be formed by forming lower hole patterns on the first region, and upper hole patterns UO may be formed on the second region. In a portion of the second region that does not overlap the first region, the lower sacrificial layers SP1 may not be formed, and only the upper hole patterns UO may be formed to pass through a second molded structure S2.

Referring to FIG. 11B, the source structure 105 is formed on the first structure 1, interlayer insulating layers and sacrificial layers are alternately stacked to form a first molded structure 51, a first capping layer 190 is formed, and first to third mask layers 211, 221 and 231 may be sequentially formed. The first mask layer 211 may be formed of, for example, an amorphous carbon layer (ACL) or a spin on hardmask (SOH). The second mask layer 221 may be, for example, a photoresist formed in a ring shape on the first ring region on the wafer 100W of FIG. 11A. The second mask layer 221 may prevent hole patterns from being formed in the first molded structure 51 in the first ring region. The third mask layer 231 may be a photoresist formed to etch hole patterns.

Referring to FIG. 11C, a first photolithography process and a first etching process may be performed to form lower holes penetrating through the first molded structure 51, and the lower holes may be filled with sacrificial layers SP1. The second molded structure S2 may be formed by alternately stacking interlayer insulating layers and sacrificial layers on the first molded structure 51, a second insulating layer 290 may be formed, and first to third mask layers 212, 222 and 232 may be formed. The first mask layer 212 may be formed of, for example, an amorphous carbon layer (ACL) or a spin on hardmask (SOH). The second mask layer 222 may be, for example, a photoresist formed in a ring shape on the second ring region on the wafer 100W of FIG. 11A. The second mask layer 222 may prevent hole patterns from being formed in the second molded structure S2 in the second ring region. The third mask layer 231 may be a photoresist formed to etch hole patterns.

Referring to FIG. 11D, a second photolithography process and a second etching process may be performed to form upper holes UO penetrating through the second molded structure S2. The upper holes UO may expose upper portions of the sacrificial layers SP1. A portion of the upper holes UO may be formed on a region in which the sacrificial layers SP1 are not formed.

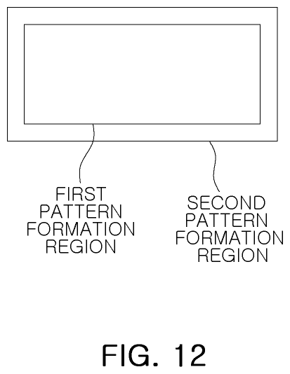

FIGS. 12 to 16B are diagrams illustrating a method of manufacturing a semiconductor device according to example embodiments. Referring to FIG. 12, in one chip unit, a first photolithography process and a first etching process may be performed on a first pattern formation region, and a second photolithography process and a second etching process may be performed on a second pattern formation region.

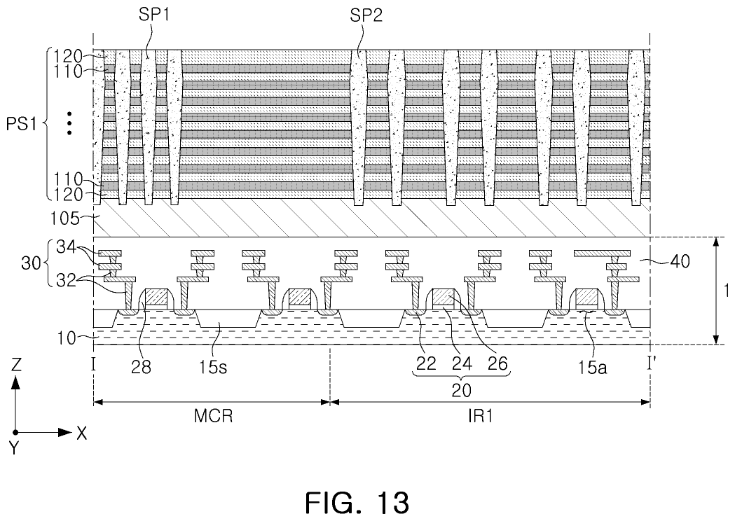

The first pattern formation region may have an area smaller than an area of the second pattern formation region. The first pattern formation region may be a region in which lower hole patterns are formed, and the second pattern formation region may be a region in which upper hole patterns are formed. Referring to FIGS. 13 to 16B together, the first pattern formation region may be a region in which the sacrificial layers SP1 and SP2 are formed, and a portion of the second pattern formation region, not overlapping the first pattern formation region may be a region in which the dummy vertical channel structures DS2 and DS3 are formed.

The dummy vertical channel structures DS2 and DS3 penetrating through only the upper stack group among the lower stack group and the upper stack group may be formed by providing the first and second pattern formation regions. This will be further described with reference to FIGS. 13 to 16B below.

Referring to FIG. 13, a first structure 1 including circuit elements 20 and a lower interconnection structure 30 may be formed on a substrate 10, a source structure 105 may be formed on the first structure 1, a first preliminary stack structure PS1 may be formed by alternately stacking the sacrificial layers 110 and the interlayer insulating layers 120, and sacrificial layers SP1 and SP2 passing through the first preliminary stack structure PS1 may be formed.

First, device isolation layers 15s may be formed in the substrate 10, and a circuit gate dielectric layer 24 and a circuit gate electrode 26 may be sequentially formed on the active region 15a. The device isolation layers 210 may be formed by, for example, a shallow trench isolation (STI) process. The circuit gate dielectric layer 24 may be formed of silicon oxide, and the circuit gate electrode 26 may be formed of at least one of polycrystalline silicon or a metal silicide layer, but is not limited thereto. Next, a spacer layer 28 may be formed on both sidewalls of the circuit gate dielectric layer 24 and the circuit gate electrode 26, and source/drain regions 22 may be formed in the active region 15a. In some embodiments, the spacer layer 28 may be formed of a plurality of layers. The source/drain regions 22 may be formed by performing an ion implantation process.

The lower contacts 32 and the lower interconnections 34 of the lower interconnection structure 30 may be formed by partially forming and partially etching and removing the lower capping layer 40 and by filling with the conductive material, or may be formed by depositing and then patterning a conductive material and filling the area in which the conductive material has been removed by patterning with a portion of the lower capping layer 40.

The lower capping layer 40 may be formed of a plurality of insulating layers. The lower capping layer 40 is partially formed in respective operations of forming the lower interconnection structure 30, and partially formed on an uppermost lower interconnection 34, to be finally formed to cover the circuit elements 20 and the lower interconnection structure 30.

Next, the source structure 105 may be formed. For example, the source structure 105 may include a conductive plate layer (101 of FIG. 5), sacrificial horizontal insulating layers (formed in a position corresponding to 102 of FIG. 5 and replaced with 102 in a subsequent process), and a second pattern layer 103.

The sacrificial layers 110 may be partially replaced by the gate electrodes 130 (refer to FIG. 3A) in a subsequent process. The sacrificial layers 110 may be formed of a material different from a material of the interlayer insulating layers 120, and may be formed of a material that may be etched with etch selectivity with respect to the interlayer insulating layers 120 under specific etching conditions. For example, the interlayer insulating layer 120 may be formed of at least one of silicon oxide and silicon nitride, and the sacrificial layers 110 may be formed of a material different from a material of the interlayer insulating layer 120, selected from among silicon, silicon oxide, silicon carbide and silicon nitride. In example embodiments, the thicknesses of the interlayer insulating layers 120 may not all be the same. The thickness of the interlayer insulating layers 120 and the sacrificial layers 110 and the number of layers constituting the interlayer insulating layers 120 and the sacrificial layers 110 may be variously changed from those illustrated. Although not illustrated, the sacrificial layers 110 and the interlayer insulating layers 120 may be etched to form a step structure on the first connection region IR1.

The sacrificial layers SP1 and SP2 may be formed by anisotropically etching the first preliminary stack structure PS1 to form hole-shaped lower holes and then filling the holes. The sacrificial layers SP1 and SP2 may include a semiconductor material such as polycrystalline silicon. The sacrificial layers SP1 and SP2 may be formed of a material having etch selectivity to the interlayer insulating layers 120 and the sacrificial layers 110. Among first sacrificial layers SP1 among the sacrificial layers SP1 and SP2 may be formed on the memory cell region MCR, and second sacrificial layers SP2 may be formed on the first connection region IR1.

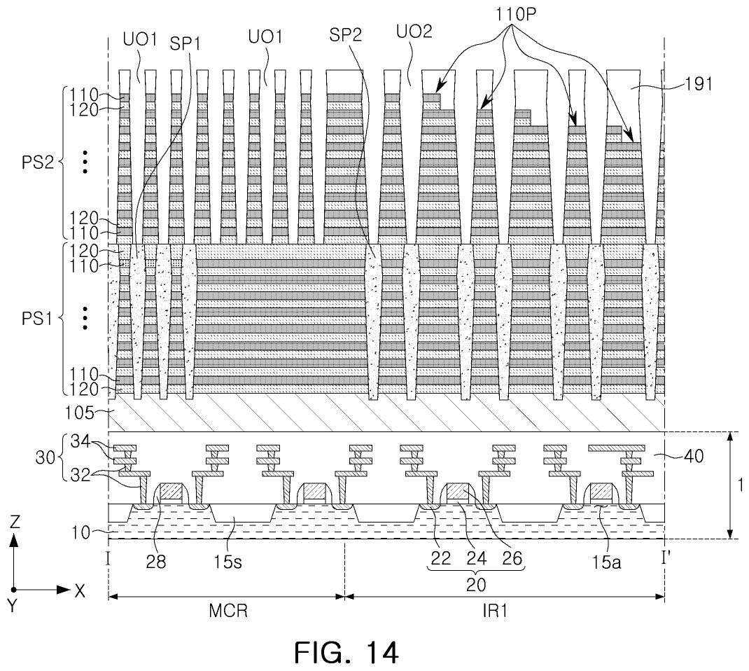

Referring to FIG. 14, a second preliminary stack structure PS2 may be formed by alternately stacking sacrificial layers 110 and interlayer insulating layers 120 on the first preliminary stack structure PS1, and upper holes UO1 and UO2 may be formed. The sacrificial layers 110 and the interlayer insulating layers 120 may be alternately stacked on the first preliminary stack structure PS1. The sacrificial layers 110 and the interlayer insulating layers 120 may be etched to form a stepped structure on the first connection region IR1, and may provide preliminary pad regions 110P.

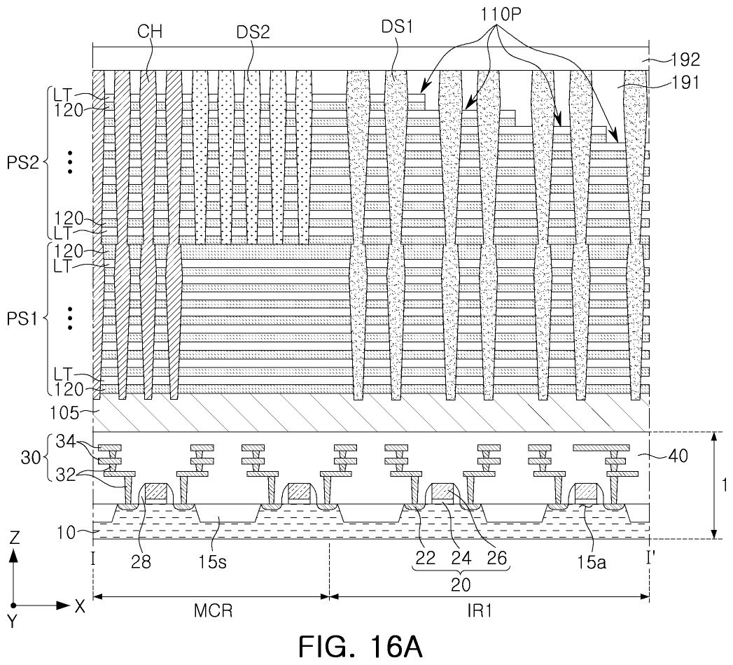

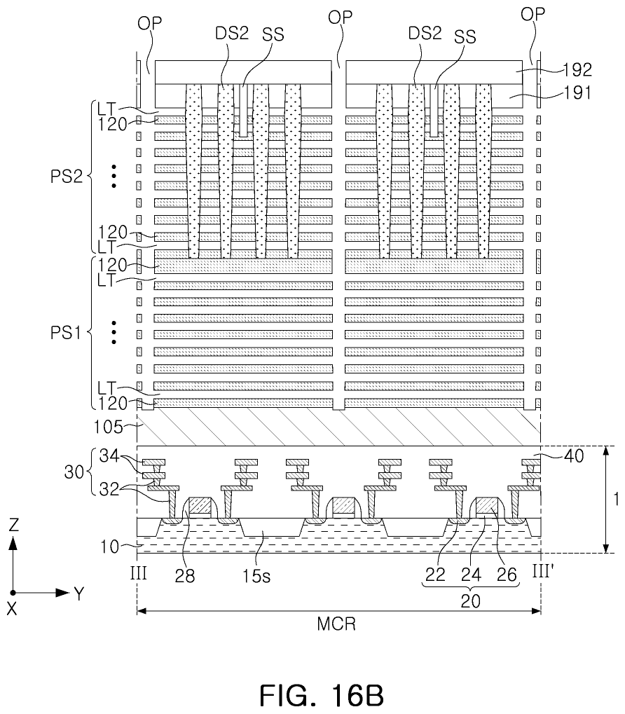

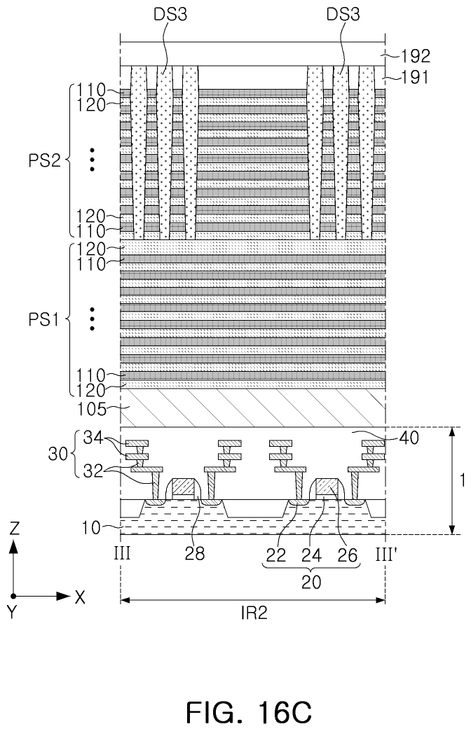

Portions of the sacrificial layers 110 and the interlayer insulating layers 120 may be removed to form an upper separation structure (refer to SS of FIG. 16B). The upper separation structure SS may be formed by using a separate mask layer to expose a region in which the upper separation structure SS is to be formed and by removing a predetermined number of the sacrificial layers 110 and the interlayer insulating layers 120 from the top and then depositing an insulating material.

The second preliminary stack structure PS2 may be anisotropically etched to form hole-shaped upper holes UO1 and UO2. The first upper holes UO1 may be formed on the memory cell region MCR, and the second upper holes UO2 may be formed on the first connection region IR1. A portion of the first upper holes UO1 may expose the first sacrificial layers SP1, and the other portions thereof may be formed on a region in which the first sacrificial layers SP1 are not formed. A portion of the first upper holes UO1 may partially penetrate through the first preliminary stack structure PS1. The second upper holes UO2 may expose the second sacrificial layers SP2. The etch depth of the first upper holes UO1 may vary according to example embodiments, and when the etch depth decreases closer to the first connection region IR1, the semiconductor device 100A of FIG. 7 may be manufactured.

Referring to FIG. 15, vertical holes may be formed by removing the sacrificial layers SP1 and SP2, and a plurality of layers may be formed in the vertical holes to form channel structures CH and dummy vertical channel structures DS1 and DS2. For example, referring to FIGS. 15 and 5 together, forming the channel structures CH may include conformally forming the gate dielectric layer 145 inside each of the vertical holes on the memory cell region MCR, forming a channel layer 140 on the gate dielectric layer 145, forming a core insulating layer 147 filling a space between inner sidewalls of the channel layer 140, and forming a channel pad 149 in an area in which an upper portion of the core insulating layer 147 has been partially removed. Like the channel structures CH, a dummy gate dielectric layer 145d, a dummy channel layer 140d, a dummy core insulating layer 147d, and a dummy channel pad 149d are sequentially deposited in each of the vertical holes, thereby forming dummy vertical channel structures DS1 and DS2. Referring to FIG. 16C below, in this operation, third dummy vertical channel structures DS3 may also be formed.

In this operation, when the epitaxial layer 107 formed by an epitaxial growth process from the source structure 105 is formed on the lower end of the channel structures CH, the process operations for forming the horizontal insulating layers, the second pattern layer 103 and the first the patterned layer 102 may be omitted. Thereafter, the semiconductor device 1006 of FIG. 8 may be manufactured by a subsequent process.

Referring to FIG. 16A, separation openings OP passing through the first and second preliminary stack structures PS1 and PS2 and extending in the X-direction may be formed, and the sacrificial layers 110 may be removed through the separation openings OP, thereby forming the horizontal openings LT.

First, a first upper capping layer 191 may be formed on an uppermost interlayer insulating layer 120, and the separation openings OP may be formed by forming a mask layer and anisotropically etching the first upper capping layer 191, the sacrificial layers 110 and the interlayer insulating layers 120, using a photolithography process. The separation openings OP may be formed in a trench shape extending in the X-direction.

To form the source structure 105 of FIG. 5, in this operation, separate sacrificial spacer layers are formed in the separation openings OP, and an etch-back process is performed to remove the horizontal sacrificial insulating layers, and then, a first patterned layer 102 may be formed between the conductive plate layer 101 and the second patterned layer 103. Thereafter, the sacrificial spacer layers may be removed. In the process of removing the horizontal sacrificial insulating layers, a portion of the gate dielectric layer 145 may also be removed to expose a lower portion of the channel layer 140. The first pattern layer 102 may be formed of a conductive material and may be in direct contact with the channel layer 140.

The sacrificial layers 110 may be selectively removed with respect to the interlayer insulating layers 120, the source structure 105, and the first upper capping layer 191. Accordingly, a plurality of horizontal openings LT may be formed between the interlayer insulating layers 120. The sacrificial layers 110 may be removed from the memory cell region MCR, and may remain on the second connection region IR2 without being removed, as illustrated in FIG. 16C. Referring to FIG. 2B together, the separation openings OP may be formed in regions in which separation structures MS1, MS2a, and MS2b are to be formed, and the etchant introduced through the separation openings OP does not reach, and thus, the sacrifice layers 110 may remain on the second connection region IR2.

Thereafter, the gate electrodes 130 may be formed in the horizontal openings LT, and the separation structures MS1a, MS2a, and MS2b may be formed in the separation openings OP. First, the gate electrodes 130 may be formed by filling the horizontal openings LT formed by removing the sacrificial layers 110 through the separation openings OP, with a conductive material. Accordingly, the stack structure ST may be formed.

Next, the separation structures MS1, MS2a, and MS2b may be formed by filling the separation openings OP with an insulating material. According to example embodiments, an isolation pattern including an insulating material and a core pattern including a conductive material may be formed in the separation openings OP.

Next, a second upper capping layer 192 is formed on the separation structures MS1, MS2a and MS2b and the first upper capping layer 191, and the gate contact structures 150 connected to the gate electrodes 130 on the first connection region IR1, and the source contact structure 160 connected to the source structure 105 on the second connection region IR2, may be formed.

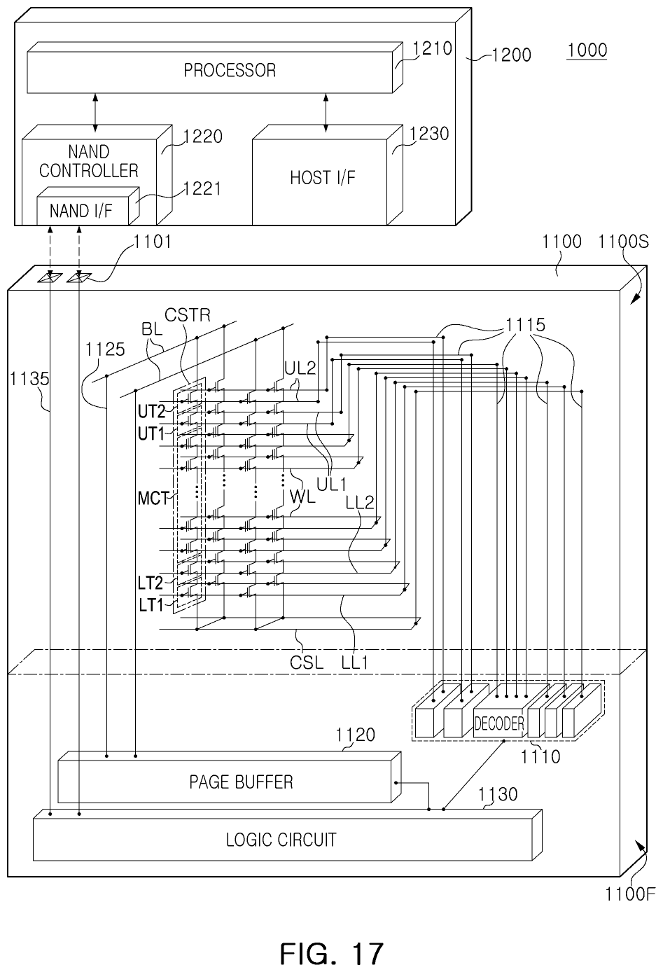

FIG. 17 is a diagram schematically illustrating a data storage system including a semiconductor device according to example embodiments. Referring to FIG. 17, a data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD), a universal serial bus (USB), a computing system, a medical device or a communication device, including one or a plurality of semiconductor devices 1100.

The semiconductor device 1100 may be a nonvolatile memory device, for example, the NAND flash memory device described above with reference to FIGS. 1 to 10. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified according to embodiments.

In example embodiments, the upper transistors UT1 and UT2 may include a string select transistor, and the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT using the GIDL phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the inside of the first structure 1100F to the second structure 1100S. The bit lines BL may be electrically connected to the page buffer 1120 through second connection interconnections 1125 extending from the inside of the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the inside of the first structure 1100F to the second structure 1100S.

The controller 1200 may include a processor 1210, a NAND controller 1220, and a host interface 1230. In some embodiments, the data storage system 1000 may include a plurality of semiconductor devices 1100, and in this case, the controller 1200 may control the plurality of semiconductor devices 1100.

The processor 1210 may control the overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 that processes communication with the semiconductor device 1100. Through the controller interface 1221, a control command for controlling the semiconductor device 1100, data to be written to the memory cell transistors MCT of the semiconductor device 1100, data to be read from the memory cell transistors MCT, and the like may be transmitted. The host interface 1230 may provide a communication function between the data storage system 1000 and an external host. When receiving a control command from an external host through the host interface 1230, the processor 1210 may control the semiconductor device 1100 in response to the control command.

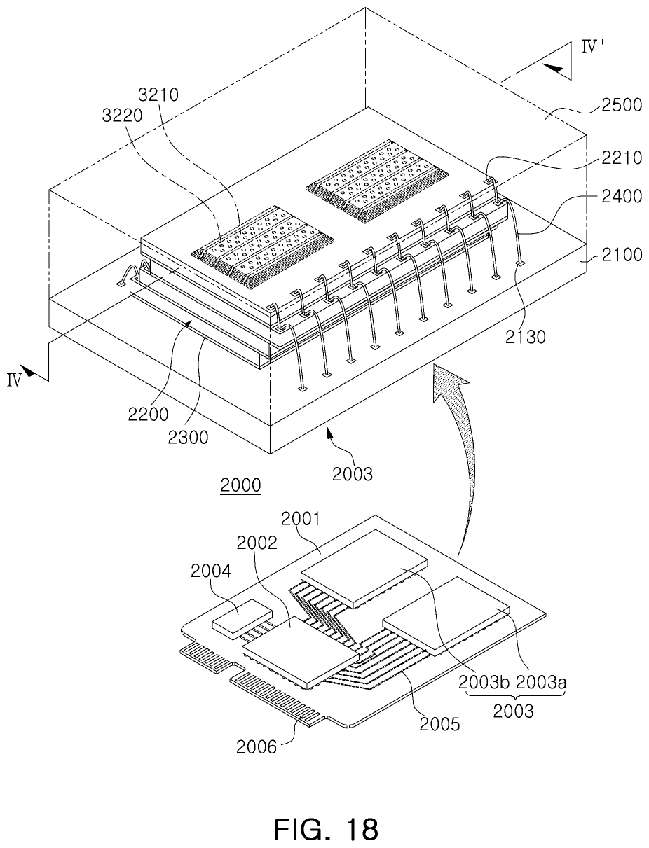

FIG. 18 is a schematic perspective view of a data storage system including a semiconductor device according to an example embodiment. Referring to FIG. 18, a data storage system 2000 according to an example embodiment of the present inventive concept may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary according to a communication interface between the data storage system 2000 and the external host. In example embodiments, the data storage system 2000 may communicate with an external host according to any one of the interfaces such as a Universal Serial Bus (USB), Peripheral Component Interconnect Express (PCI-Express), Serial Advanced Technology Attachment (SATA), an M-Phy for Universal Flash Storage (UFS), and the like. In example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or read data from the semiconductor package 2003, and may improve the operating speed of the data storage system 2000. The DRAM 2004 may be a buffer memory for reducing a speed difference between the semiconductor package 2003 as a data storage space and an external host. The DRAM 2004 included in the data storage system 2000 may also operate as a kind of cache memory, and may provide a space for temporarily storing data in a control operation for the semiconductor package 2003. For example, when the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on lower surfaces of the semiconductor chips 2200, respectively, a connection structure 2400 electrically connecting the semiconductor chips 2200 and the package substrate 2100, and a molded layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 17. Each of the semiconductor chips 2200 may include gate stack structures 3210 and channel structures 3220. Each of the semiconductor chips 2200 may include the semiconductor device described above with reference to FIGS. 1 to 10.

In example embodiments, the connection structure 2400 may be a bonding wire electrically connecting the input/output pad 2210 and the upper package pads 2130. Accordingly, in each of the first and second semiconductor packages 2003a and 2003b, the semiconductor chips 2200 may be electrically connected to each other by a bonding wire method, and may be electrically connected to the upper package pads 2130 of the package substrate 2100. According to example embodiments, in each of the first and second semiconductor packages 2003a and 2003b, the semiconductor chips 2200 may also be electrically connected to each other by a connection structure including a Through Silicon Via (TSV) instead of the connection structure 2400 of the bonding wire method.

In example embodiments, the controller 2002 and the semiconductor chips 2200 may be included in one package. In an example embodiment, the controller 2002 and the semiconductor chips 2200 may be mounted on a separate interposer substrate different from the main board 2001, and the controller 2002 and the semiconductor chips 2200 may be connected to each other by interconnections formed on the interposer substrate.

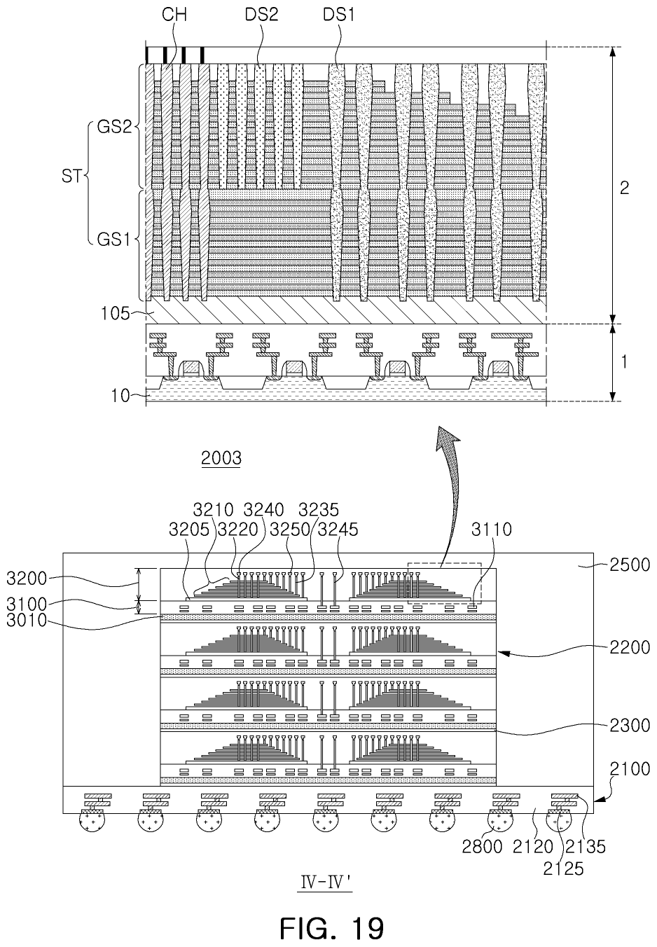

FIG. 19 is a cross-sectional view schematically illustrating a semiconductor package according to an example embodiment. FIG. 19 illustrates an example embodiment of the semiconductor package 2003 of FIG. 18, and conceptually illustrates a region taken along line IV-IV′ of the semiconductor package 2003 of FIG. 18. Referring to FIG. 19, in the semiconductor package 2003, the package substrate 2100 may be a printed circuit board. The package substrate 2100 may include a package substrate body 2120, package upper pads 2130 (see FIG. 18) disposed on an upper surface of the package substrate body 2120, lower pads 2125 disposed on or exposed through the lower surface of the package substrate body 2120, and internal interconnections 2135 electrically connecting the upper pads 2130 and the lower pads 2125 inside the package substrate body 2120. The upper pads 2130 may be electrically connected to the connection structures 2400. The lower pads 2125 may be connected to the interconnection patterns 2005 of the main board 2001 of the data storage system 2000 as illustrated in FIG. 18 through conductive connection portions 2800.

Each of the semiconductor chips 2200 may include a semiconductor substrate 3010, and a first structure 3100 and a second structure 3200 that are sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 and separation regions 3230 passing through the gate stack structure 3210, bit lines 3240 electrically connected to the memory channel structures 3220, and gate contact plugs 3235 electrically connected to the word lines WL of the gate stack structure 3210 (see FIG. 17). As described above with reference to FIGS. 1 to 10, each of the semiconductor chips 2200 may include a substrate 10, a source structure 105, a stack structure ST including first and second stack groups GS1 and GS2, channel structures (CH), and dummy vertical channel structures DS1 and DS2.

Each of the semiconductor chips 2200 may include a through interconnection 3245 electrically connected to the peripheral interconnections 3110 of the first structure 3100 and extending into the second structure 3200. The through interconnection 3245 may be disposed outside the gate stack structure 3210, and may be further disposed to pass through the gate stack structure 3210. Each of the semiconductor chips 2200 may further include an input/output pad 2210 (refer to FIG. 18) electrically connected to the peripheral interconnections 3110 of the first structure 3100.

As set forth above, by disposing dummy vertical channel structures passing through only the upper stack group among the lower stack group and the upper stack group, a semiconductor device having improved reliability and a data storage system including the same may be provided.

While example embodiments have been illustrated and described above, it will be apparent to those skilled in the art that modifications and variations could be made without departing from the scope of the present inventive concept as defined by the appended claims.

1.-10. (canceled)

11. A semiconductor device, comprising:
a source structure including a memory cell region and a first connection region;
a stack structure disposed on the source structure and including a first gate stack group and a second gate stack group on the first gate stack group, the first gate stack group including a plurality of first gate electrodes, and the second gate stack group including a plurality of second gate electrodes;
a plurality of channel structures penetrating through the stack structure and connected to the source structure, on the memory cell region;
a plurality of first dummy vertical structures passing through at least a portion of the stack structure, on the first connection region; and
a plurality of second dummy vertical structures passing through the second gate stack group, on the memory cell region, and disposed between the plurality of channel structures and the plurality of first dummy vertical structures,
wherein each of the plurality of channel structures includes a lower channel structure passing through the first gate stack group and an upper channel structure passing through the second gate stack group,
the plurality of second dummy vertical structures penetrate through an uppermost second gate electrode among the plurality of second gate electrodes, and
lower ends of the plurality of second dummy vertical structures are disposed on a level higher than a level of at least one of the plurality of first gate electrodes.

12. The semiconductor device of claim 11, wherein the plurality of first and second gate electrodes extending in a first direction to provide first and second pad regions, respectively, the first and second pad regions forming a step structure on the first connection region, and
the plurality of first dummy vertical structures pass through the first and second pad regions.

13. The semiconductor device of claim 12, wherein the plurality of second dummy vertical structures are spaced apart from the first and second pad regions.

14. The semiconductor device of claim 11, wherein the plurality of second dummy vertical structures are spaced apart from the plurality of first gate electrodes.

15. The semiconductor device of claim 11, wherein each of the plurality of channel structures includes a bent portion provided by a difference between a width of an upper end of the lower channel structure and a width of an lower end of the upper channel structure.

16. The semiconductor device of claim 11, wherein the plurality of second dummy vertical structures include a first vertical pattern and a second vertical pattern,
wherein the first vertical pattern is disposed closer to the plurality of channel structures than the second vertical pattern, and
a vertical length of the first vertical pattern is greater than a vertical length of the second vertical pattern.

17. The semiconductor device of claim 11, wherein the source structure further includes a second connection region, and
the stack structure further includes a plurality of first sacrificial layers disposed on the same level as the plurality of first gate electrodes and a plurality of second sacrificial layers disposed on the same level as the plurality of second gate electrodes, on the second connection region.

18. The semiconductor device of claim 17, further comprising, on the second connection region, a plurality of third dummy vertical structures passing through the plurality of second sacrificial layers and having lower ends disposed on a level higher than a level of at least one of the plurality of first sacrificial layers.

19. The semiconductor device of claim 18, wherein the plurality of third dummy vertical structures are spaced apart from the plurality of first sacrificial layers.

20. The semiconductor device of claim 18, further comprising a source contact structure penetrating through the plurality of first and second sacrificial layers and connected to the source structure, on the second connection region.

21. The semiconductor device of claim 20, wherein the source contact structure is disposed between the plurality of third dummy vertical structures.

22. The semiconductor device of claim 11, wherein each of the plurality of channel structures includes a core insulating layer, a channel layer covering side surfaces of the core insulating layer, and a gate dielectric layer between the channel layer and the plurality of first and second gate electrodes, and
each of the plurality of second dummy vertical structures includes a dummy core insulating layer, a dummy channel layer covering side surfaces of the dummy core insulating layer, and a dummy gate dielectric layer between the dummy channel layer and the plurality of second gate electrodes.

23. The semiconductor device of claim 11, wherein the stack structure further includes a third gate stack group between the first gate stack group and the second gate stack group;
the third gate stack group includes a plurality of third gate electrodes, and
each of the plurality of channel structures further includes an intermediate channel structure passing through the third gate stack group and connected to the lower channel structure and the upper channel structure.

24. A semiconductor device, comprising:
a source structure including a memory cell region, a first connection region, and a second connection region;
a plurality of gate electrodes stacked on the memory cell region of the source structure and including pad regions extending in a first direction and forming a step structure on the first connection region, the plurality of gate electrodes including a first gate stack group and a second gate stack group on the first gate stack group;
a plurality of sacrificial layers stacked on the second connection region of the source structure and disposed on the same level as the gate electrodes, the plurality of sacrificial layers including a first sacrificial stack group and a second sacrificial stack group on the first sacrificial stack group;
a plurality of channel structures connected to the source structure by penetrating through the plurality of gate electrodes, on the memory cell region;
a plurality of first dummy vertical structures passing through the pad regions of the plurality of gate electrodes, on the first connection region; and
a plurality of second dummy vertical structures passing through the second sacrificial stack group, on the second connection region.

25. The semiconductor device of claim 24, wherein lower ends of the plurality of second dummy vertical structures are disposed on a level higher than a level of at least one of the plurality of sacrificial layers of the first sacrificial stack group.

26. The semiconductor device of claim 24, further comprising a source contact structure connected to the source structure by penetrating through the first and second sacrificial stack groups, on the second connection region.

27. The semiconductor device of claim 24, wherein the plurality of second dummy vertical structures are spaced apart from the plurality of sacrificial layers of the first sacrificial stack group.

28. The semiconductor device of claim 24, further comprising a plurality of third dummy vertical structures spaced apart from the pad regions and penetrating through the second gate stack group.

29. A data storage system comprising:
a semiconductor storage device including a lower structure including a substrate and circuit elements on the substrate, an upper structure on the lower structure, and an input/output pad electrically connected to the circuit elements; and
a controller electrically connected to the semiconductor storage device through the input/output pad and controlling the semiconductor storage device,
wherein the upper structure includes,
a source structure including a memory cell region and a first connection region;
a stack structure disposed on the source structure and including a first gate stack group and a second gate stack group on the first gate stack group, the first gate stack group including a plurality of first gate electrodes, and the second gate stack group including a plurality of second gate electrodes;
a plurality of channel structures connected to the source structure by penetrating through the stack structure, on the memory cell region;
a plurality of first dummy vertical structures passing through at least a portion of the stack structure, on the first connection region; and
a plurality of second dummy vertical structures passing through the second gate stack group, on the memory cell region, and disposed between the plurality of channel structures and the plurality of first dummy vertical structures,
wherein lower ends of the plurality of second dummy vertical structures are disposed on a level higher than a level of the plurality of first gate electrodes,
the plurality of first and second gate electrodes provide first and second pad regions, respectively, the first and second pad regions extending in a first direction and forming a step structure on the first connection region, and
the plurality of second dummy vertical structures are spaced apart from the first and second pad regions.

30. The data storage system of claim 29, wherein the source structure further includes a second connection region, and
the stack structure further includes a plurality of first sacrificial layers disposed on the same level as the plurality of first gate electrodes and a plurality of second sacrificial layers disposed on the same level as the plurality of second gate electrodes, on the second connection region,
wherein the data storage system further comprises a plurality of third dummy vertical structures disposed on the second connection region, passing through the plurality of second sacrificial layers, and having lower ends disposed on a level higher than a level of at least one of the plurality of first sacrificial layers.

31.-32. (canceled)
